(19) United States
(12) Patent Application Publication
(10) Pub. No.: US 2010/0006884 A1
(43) Pub. Date: Jan. 14, 2010

(54) Light Emitting Device and Manufacturing Method Therof

(75) Inventors: Chen Ou, Hsinchu (TW); Chen-Ke Hsu, Hsinchu (TW); Chia-Ming Chuang, Hsinchu (TW)

Correspondence Address: BACON & THOMAS, PLLC, 625 SLATERS LANE, FOURTH FLOOR, ALEXANDRIA, VA, 22314-1176, US

(73) Assignee: Epistar Corporation, Hsinchu (TW)

(21) Appl. No.: 12/585,420

(22) Filed: Sep. 15, 2009

Related U.S. Application Data
(63) Continuation-in-part of application No. 11/890,493, filed on Aug. 7, 2007.

(30) Foreign Application Priority Data
Sep. 18, 2008 (TW) 097135940

(51) Int. Cl. H01L 33/00

(52) U.S. Cl. 257/98; 438/38; 257/E33.005; 257/E33.074

(57) ABSTRACT

The application relates to a structure of a light emitting device and the manufacturing method thereof. The application discloses a method of forming a bonding pad of the light emitting device by chemical deposition method. The light emitting device includes a substrate, a semiconductor stack deposited on the substrate wherein the semiconductor stack includes at least a p-type semiconductor layer, an n-type semiconductor layer, and an active layer disposed between the p-type semiconductor layer and the n-type semiconductor layer. A bonding pad is formed on at least one of the p-type semiconductor layer and the n-type semiconductor layer wherein the bonding pad includes a seed layer formed by physical deposition method, and a chemically-deposited layer formed by chemical deposition method. The thickness of the seed layer is smaller than that of the chemically-deposited layer.

### REFERENCE TO RELATED APPLICATION

This application is a continuation-in-part of U.S. patent application Ser. No. 11/890,493, entitled “METHOD FOR MAKING A LIGHT EMITTING DIODE BY ELECTROLESS PLATING”, filed on Aug. 7, 2007, and claims the right of priority based on TW application Ser. No. 097135940, filed Sep. 18, 2008, entitled “LIGHT EMITTING DEVICE AND MANUFACTURING METHOD THEROF”, and the contents of which are incorporated herein by reference.

### BACKGROUND

1. Technical Field

A light emitting device and manufacturing method therof is disclosed, especially is related to a method of forming a bonding pad on the light emitting device by a chemical deposition method.

2. Description of the Related Art

In a known method of making a light-emitting diode, several epitaxial layers on which a bonding pad is disposed are formed on a growth substrate. The epitaxial layers include an n-type semiconductor layer, a p-type semiconductor layer, and an active layer between the n-type semiconductor layer and the p-type semiconductor layer.

The bonding pads usually electrically connect to the n-type and p-type semiconductor layers by wire-bonding or flip-chip technology. Therefore, metal is chosen to be the material of the bonding pad in principle because it can bear the impact of wire-bonding with an appropriate thickness.

In general, the bonding pads are formed by physical deposition method such as thermal evaporation, e-beam evaporation or ion-sputtering. Owing to the omni-directional characteristic of the physical deposition, the material tends to cover the area not designated for the bond pad, and then needs to be removed. It will cause the waste, and increase the manufacturing cost when the materials of the bonding pads are precious metals such as gold.

Besides, many light emitting diodes use surface roughening techniques to increase light extracting efficiency. In general, the surface of the bonding pads formed by physical deposition method is also rough because of the rough surface of the light emitting diodes. The rough surfaces make the identification difficult in the wire bonding in the packaging process of light emitting device.

### SUMMARY

A light emitting device and manufacturing method therof is disclosed, especially is related to a process of forming a bonding pad on the light emitting device by chemical deposition method. The light emitting device comprises: a substrate; a semiconductor epitaxial structure formed on the substrate, the semiconductor epitaxial structure comprising a p-type semiconductor layer, an n-type semiconductor layer, and a light-emitting region between the p-type semiconductor layer and the n-type semiconductor layer; a bonding pad located on at least one of the p-type semiconductor layer and the n-type semiconductor layer; wherein the bonding pad having a seed layer formed by physical deposition method and a chemically-deposited layer formed by chemical deposition method, wherein the thickness of the seed layer is smaller than the thickness of the chemically-deposited layer.

The materials of the seed layer and the chemically-deposited layer can be the same with different crystal morphologies, and the grain size of the seed layer can be larger than the grain size of the chemically-deposited layers.

The seed layer or the chemically-deposited layer can be a multi-layer structure wherein at least one layer of the multi-layer structure in the seed layer or in the chemically-deposited layer has the same composition as that of at least one layer in the other structure, wherein the two layers having the same composition have different crystal morphologies. For example, one layer of the seed layer has the same material with the chemically-deposited layer, but has larger grain size than the chemically-deposited layer.

The upper surfaces of the semiconductor epitaxial layer, the seed layer and the chemically-deposited layer can be rough surfaces. The roughness of the upper surface of the seed layer is smaller than the roughness of the upper surface of the semiconductor epitaxial layer, and the roughness of the upper surface of the chemically-deposited layer is smaller than the roughness of the upper surface of the seed layer.

### BRIEF DESCRIPTION OF THE DRAWINGS

The accompanying drawings are included to provide easy understanding of the application, and are incorporated herein and constitute a part of this specification. The drawings illustrate embodiments of the application and, together with the description, serve to illustrate the principles of the application.

FIG. 1 illustrates a flow chart of the manufacturing of the semiconductor light-emitting device in accordance with the present application.

FIG. 2 illustrates cross-sectional view of the semiconductor light-emitting device in accordance with an embodiment of the present application.

FIG. 3 illustrates cross-sectional view of the semiconductor light-emitting device in accordance with an embodiment of the present application.

FIG. 4 illustrates cross-sectional view of the semiconductor light-emitting device in accordance with an embodiment of the present application.

FIG. 5 illustrates cross-sectional view of the semiconductor light-emitting device in accordance with an embodiment of the present application.

### DESCRIPTION OF THE PREFERRED EMBODIMENTS

Reference is made in detail to the preferred embodiments of the present application, examples of which are illustrated in the accompanying drawings. Wherever possible, the same reference numbers are used in the drawings and the description to refer to the same or like parts.

A light emitting device and manufacturing method therof is disclosed, is especially related to a method of forming a bonding pad on the light emitting device by chemical deposition method.

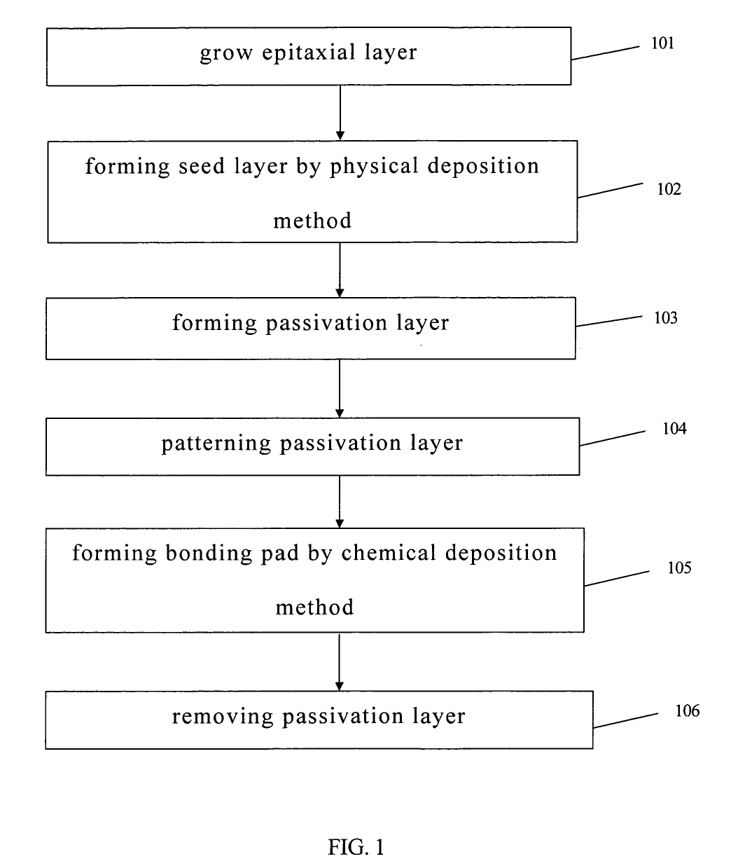

FIG. 1 illustrates a flow chart of forming a bonding pad by chemical deposition method. First, in step 101, an epitaxial structure of a light-emitting diode is formed. The epitaxial structure includes a substrate, an n-type semiconductor layer, a p-type semiconductor layer, and a light-emitting layer between the n-type semiconductor layer and the p-type semiconductor layer.

In step 102, a metal layer or a conductive layer is then formed on the epitaxial structure to serve as a seed layer.

In step 103, a passivation layer or an insulating layer is formed on surfaces of the epitaxial structure not covered by the seed layer.

In step 104, a bonding pad pattern is formed on the passivation layer or the insulating layer by photolithography, which is known to the person having ordinary skill in the art and not explained in further detail.

In step 105, a chemical deposition method is performed on at least a part of aforementioned seed layer or a part of the structure where a chemically-deposited layer is formed so that the metal ions are reduced to metal deposited on the seed layer to form the bonding pad.

In step 106, the passivation layer or the insulating layer is removed by a method including but not limited to wet etching or dry etching.

The method of present application is illustrated by manufacturing a horizontal type light-emitting diode. The so-called “horizontal type light-emitting diode” herein means a structure having a p-bonding pad and an n-bonding pad located on the same sides of a substrate. The composition of the light-emitting diode includes but is not limited to II-VI group compound, III-V group compound, group III-Nitride compound, or the combination thereof. The technology to form the horizontal type light-emitting diode by the aforementioned composition is known to the person having ordinary skill in the art and not explained in further detail.

### THE FIRST EMBODIMENT

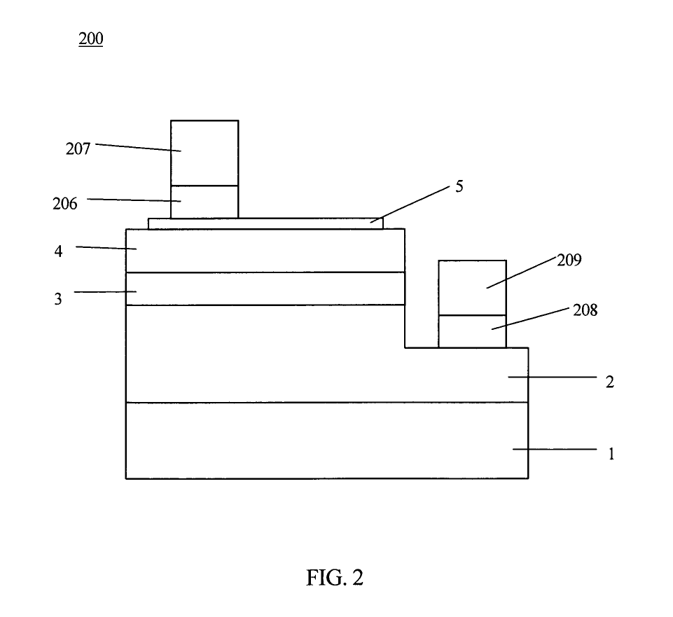

FIG. 2 illustrates a cross-sectional view of an epitaxial structure of a horizontal type light-emitting diode. The epitaxial structure includes a substrate 1, an n-type semiconductor layer 2, a light-emitting layer 3, and a p-type semiconductor layer 4. A transparent conductive layer 5 is optionally formed on the p-type semiconductor layer 4 to serve as a current spreading layer or a window layer. A seed layer 206 is formed on the transparent conductive layer 5 and another seed layer 208 is formed on the n-type semiconductor layer 2. Chemically-deposited layers 207, 209 are formed on the seed layers 206, 208 respectively.

The material of the substrate 1 herein includes but is not limited to AlGaInP, AlGaAs, GaAs, SiC, Si, AlN, sapphire, CVD diamond, ceramic, composite material, glass, or any materials suitable for horizontal type light-emitting diode. The transparent conductive layer 5 can be formed by chemical vapor deposition, physical vapor deposition, or sputtering. The material of the transparent conductive layer 5 includes but is not limited to ITO, CTO, IZO, AZO, ZnO, or the conductive metal such as Ni/Au. The seed layers 206, 208 can be formed by physical deposition method such as thermal evaporation, e-beam evaporation, or ion-sputtering. The material of the seed layers 206, 208 can be metal or conductive material wherein the metal includes but is not limited to Au, Cu, Ni, or any materials suitable for the seed layer by chemical deposition method. The thickness of each of the seed layers 206, 208 is about 100 Å˜10000 Å and the two seed layers 206, 208 can have the same composition.

The chemically-deposited layers 207, 209 are formed on the seed layers by chemical deposition method such as electroplating or electroless plating. The material of the chemically-deposited layers can be metal or conductive material wherein the metal includes but is not limited to Au, Cu, Ni, or other metals. The thickness of the chemically-deposited layer is about 0.5 μm˜3 μm and the thickness of the seed layer is sufficient for stably forming the chemically-deposited layer. In a preferred embodiment, the thickness of the seed layer is smaller than that of the chemically-deposited layer to reduce the material consumption in manufacturing the seed layer and lower the cost of manufacturing. The materials of seed layer and the chemically-deposited layer can be the same composition but have different crystal morphologies. In a preferred embodiment, the grain size of the seed layer is larger than the grain size of the chemically-deposited layer.

### THE SECOND EMBODIMENT

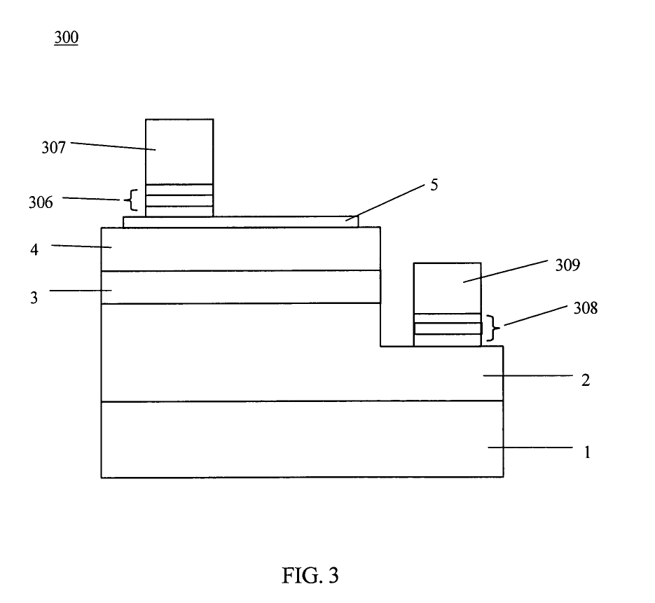

FIG. 3 illustrates a cross-sectional view of an epitaxial structure of a horizontal type light-emitting diode. The epitaxial structure includes a substrate 1, an n-type semiconductor layer 2, a light-emitting layer 3, and a p-type semiconductor layer 4. A transparent conductive layer 5 is optionally formed on the p-type semiconductor layer 4 to serve as a current spreading layer or a window layer. A seed layer 306 is formed on the transparent conductive layer 5 and another seed layer 308 is formed on the n-type semiconductor layer 2. Chemically-deposited layers 307, 309 are formed on the seed layers 306, 308, respectively.

The material of the substrate 1 herein includes but is not limited to AlGaInP, AlGaAs, GaAs, SiC, Si, AlN, sapphire, CVD diamond, ceramic, composite material, glass, or any materials suitable for horizontal type light-emitting diode. The transparent conductive layer 5 can be formed by chemical vapor deposition, physical vapor deposition, or sputtering. The material of the transparent conductive layer 5 includes but is not limited to ITO, CTO, IZO, AZO, ZnO, or the conductive metal such as Ni/Au. The seed layers 306, 308 can be formed by physical deposition method such as thermal evaporation, e-beam evaporation, or ion-sputtering. The material of the seed layers 306, 308 can be metal or conductive material wherein the metal includes but is not limited to Au, Cu, Ni, or any materials suitable for the seed layer by chemical deposition method. The thickness of each of the seed layers is about 100 Å˜10000 Å and the two seed layers 306, 308 can have the same composition.

The chemically-deposited layers 307, 309 are formed on the seed layers by chemical deposition method such as electroplating or electroless plating. The seed layers or the chemically-deposited layers can be a multi-layer structure wherein at least one layer of the multi-layer in the seed layer or in the chemically-deposited layer has the same composition as that of at least one layer in the other structure, but has different crystallization morphologies. For example, one layer of the seed layer has the same material with the chemically-deposited layer, but has larger grain size than the chemically-deposited layer.

### THE THIRD EMBODIMENT

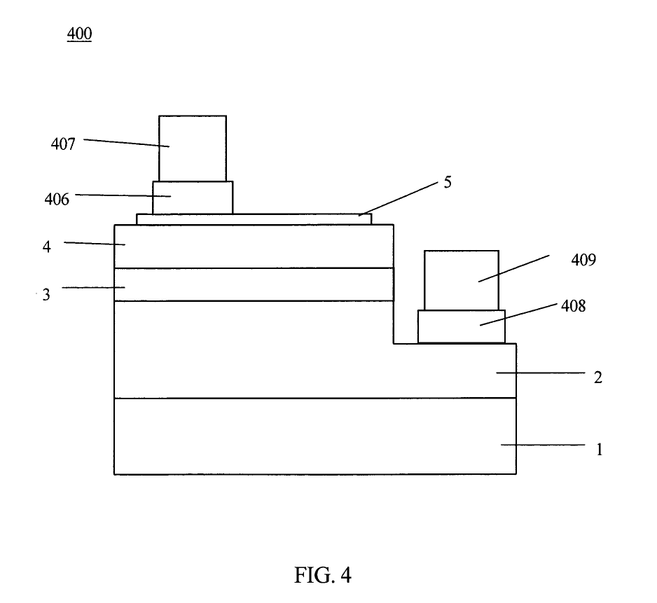

FIG. 4 illustrates a cross-sectional view of an epitaxial structure of a horizontal type light-emitting diode. The epitaxial structure includes a substrate 1, an n-type semiconductor layer 2, a light-emitting layer 3, and a p-type semiconductor layer 4. A transparent conductive layer 5 is optionally formed on the p-type semiconductor layer 4 to serve as a current spreading layer or a window layer. A seed layer 406 is formed on the transparent conductive layer 5, and another seed layer 408 is formed on the n-type semiconductor layer 2. Chemically-deposited layers 407, 409 are formed on the seed layers 406, 408, respectively.

The material of the substrate 1 herein includes but is not limited to AlGaInP, AlGaAs, GaAs, SiC, Si, AlN, sapphire, CVD diamond, ceramic, composite material, glass, or any materials suitable for horizontal type light-emitting diode. The transparent conductive layer 5 can be formed by chemical vapor deposition, physical vapor deposition, or sputtering. The material of the transparent conductive layer 5 includes but is not limited to ITO, CTO, IZO, AZO, ZnO, or the conductive metal such as Ni/Au. The seed layers 406, 408 can be formed by physical deposition method such as thermal evaporation, e-beam evaporation, or ion-sputtering. The material of the seed layers 406, 408 can be metal or conductive material wherein the metal includes but is not limited to Au, Cu, Ni, or any materials suitable for the seed layer by chemical deposition method. The thickness of each of the seed layers is about 100 Å˜10000 Å and the two seed layers 406, 408 can have the same composition.

The chemically-deposited layers 407, 409 are formed on the seed layers by chemical deposition method such as electroplating or electroless plating. The grain size of the seed layer can be larger than the grain size of the chemically-deposited layer. In a preferred embodiment, the thickness of the seed layer is smaller than the thickness of the chemically-deposited layer and the area of the seed layer is different from the area of the chemically-deposited layer. For example, the area of the seed layer is lager than the area of the chemically-deposited layer.

### THE FOURTH EMBODIMENT

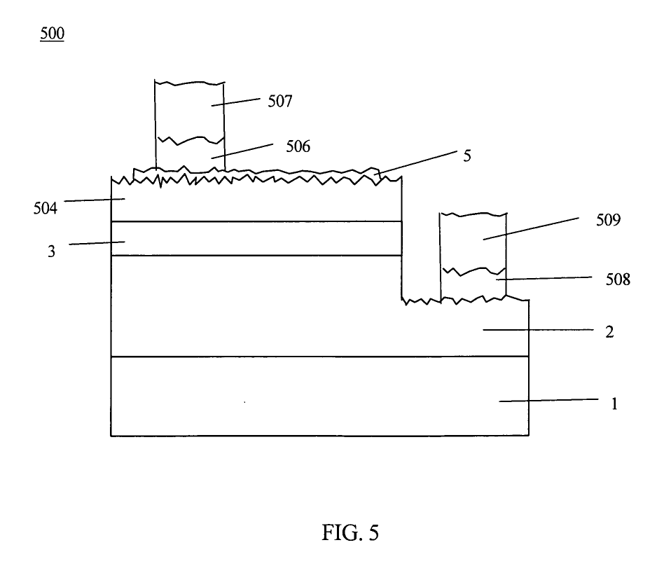

FIG. 5 illustrates a cross-sectional view of an epitaxial structure of a horizontal type light-emitting diode. The epitaxial structure includes a substrate 1, an n-type semiconductor layer 2, a light-emitting layer 3, and a p-type semiconductor layer 4. A transparent conductive layer 5 is optionally formed on the p-type semiconductor layer 4 to serve as a current spreading layer or a window layer. A seed layer 506 is formed on the transparent conductive layer 5 and another seed layer 508 is formed on the n-type semiconductor layer 2. Chemically-deposited layers 507, 509 are formed on the seed layers 506, 508, respectively. In this embodiment, the surface of the semiconductor epitaxial structure has a rough structure. The rough structure can be a shape of protruding island formed by an epitaxy method, or a shape of multi-cavities, concave cavities such as hexagonal-pyramid cavities, or irregular rough structure formed by chemical etching method.

The material of the substrate 1 herein includes but is not limited to AlGaInP, AlGaAs, GaAs, SiC, Si, AlN, sapphire, CVD diamond, ceramic, composite material, glass, or any materials suitable for horizontal type light-emitting diode. The transparent conductive layer 5 can be formed by chemical vapor deposition, physical vapor deposition, or sputtering. The material of the transparent conductive layer 5 includes but is not limited to ITO, CTO, IZO, AZO, ZnO, or the conductive metal such as Ni/Au. The seed layers 506, 508 can be formed by physical deposition method such as thermal evaporation, e-beam evaporation or ion-sputtering. The material of the seed layers 506, 508 can be metal or conductive material wherein the metal includes but is not limited to Au, Cu, Ni, or any materials suitable for the seed layer by chemical deposition method. The thickness of each of the seed layers is about 100 Å˜10000 Å and the two seed layers 506, 508 can have the same composition.

The chemically-deposited layers 507, 509 are formed on the seed layers by chemical deposition method such as electroplating or electroless plating. The thickness of the seed layer is smaller than the thickness of the chemically-deposited layer and the grain size of the seed layer is larger than the grain size of the chemically-deposited layer.

Besides the semiconductor epitaxial structure, the surfaces of the seed layers and the chemically-deposited layers can be rough surfaces. The roughness of the upper surface of the seed layer is smaller than the roughness of the upper surface of the semiconductor epitaxial layer, and the roughness of the upper surface of the chemically-deposited layer is smaller than the roughness of the upper surface of the seed layer.

In the aforementioned embodiments, the bonding pads are formed on the p-type semiconductor layer and the n-type semiconductor layer at the same time, but it can be formed on only one of the sides. Besides, the aforementioned embodiments take the horizontal type light-emitting diode as examples, but the application can also be used in the vertical type light-emitting diode.

The foregoing description has been directed to the specific embodiments of this application. It will be apparent; however, that other variations and modifications may be made to the embodiments without escaping the spirit and scope of the application.

What is claimed is:

1. A method of manufacturing a light-emitting structure, comprising:
providing a substrate;
forming a semiconductor epitaxial structure on the substrate, the semiconductor epitaxial structure comprising a p-type semiconductor layer, an n-type semiconductor layer, and a light-emitting layer between the p-type semiconductor layer and the n-type semiconductor layer;
forming a seed layer on at least one of the p-type semiconductor layer and the n-type semiconductor layer by physical deposition method; and
forming a chemically-deposited layer on the seed layer by chemical deposition method.

2. The method of claim 1, wherein the physical deposition method comprises thermal evaporation, e-beam evaporation, or ion-sputtering, and the chemical deposition method comprises electroplating or electroless plating.

3. The method of claim 1, further comprising forming a passivation layer on surfaces of the semiconductor epitaxial structure not covered by the seed layer.

4. The method of claim 1, further comprising roughening at least one of the upper surfaces of the semiconductor epitaxial structure, the seed layer, and the chemical deposition layer.

5. The method of claim 4, wherein the roughening comprises the method of epitaxy or chemical etching method.

6. A light-emitting structure, comprising:
a substrate;
a semiconductor epitaxial structure on the substrate wherein the semiconductor epitaxial structure comprising a p-type semiconductor layer, an n-type semiconductor layer, and a light-emitting layer between the p-type semiconductor layer and the n-type semiconductor layer; and
a bonding pad formed on at least one of the p-type semiconductor layer and the n-type semiconductor layer wherein the bonding pad comprises a seed layer and a chemically-deposited layer, and a thickness of the seed layer is smaller than a thickness of the chemically-deposited layer.

7. The light-emitting structure of claim 6, further comprising a transparent conductive layer formed on the semiconductor epitaxial structure.

8. The light-emitting structure of claim 7, wherein a material of the transparent conductive layer is selected from a group consisting of ITO, CTO, IZO, AZO, and transparent conductive metal.

9. The light-emitting structure of claim 6, wherein the thickness of the seed layer is about 100 Å˜10000 Å and the thickness of the chemically-deposited layer is about 0.5 μm˜3 μm.

10. The light-emitting structure of claim 6, wherein a material of the seed layer or the chemically-deposited layer is selected from a group consisting of Au, Cu, Ni, and Al.

11. The light-emitting structure of claim 6, wherein materials of the seed layer and the chemically-deposited layer are the same but have different crystal morphologies.

12. The light-emitting structure of claim 6, wherein materials of the seed layer and the chemically-deposited layer are the same, but a grain size of the seed layer is larger than a grain size of the chemical deposition layer.

13. The light-emitting structure of claim 6, wherein the seed layer or the chemically-deposited layer is a multi-layer structure.

14. The light-emitting structure of claim 13, wherein at least one layer of the multi-layer structure of the seed layer or the chemical deposition layer has the same composition as that of the multi-layer structure of the other layer, but the two layers have different crystal morphologies.

15. The light-emitting structure of claim 6, wherein an area of the seed layer and an area of the chemically-deposited layer is different.

16. The light-emitting structure of claim 15, wherein the area of the seed layer is larger than the area of the chemically-deposited layer.

17. The light-emitting structure of claim 6, wherein at least one of upper surfaces of the semiconductor epitaxial structure, the seed layer and the chemical deposition layer is a rough surface.

18. The light-emitting structure of claim 17, wherein the rough surface is protruding island shape, multi-cavities, concave cavities, hexagonal-pyramid cavities, or irregular rough structure.

19. The light-emitting structure of claim 17, wherein a roughness of the upper surface of the seed layer is smaller than a roughness of the upper surface of the semiconductor epitaxial structure.

20. The light-emitting structure of claim 17, wherein a roughness of the upper surface of the chemically-deposited layer is smaller than a roughness of the upper surface of the seed layer.
